(19) United States
(12) Patent Application Publication
(10) Pub. No.: US 2011/0014372 A1
(43) Pub. Date: Jan. 20, 2011

(54) Passivation of thermal cracking furnace conduit

(76) Inventors: Kenneth M. Webber, Friendswood, TX (US); Robert J. Haynal, Houston, TX (US); Robert W. Mason, Missouri City, TX (US)

Correspondence Address: LyondellBasell Industries, 3801 WEST CHESTER PIKE, NEWTOWN SQUARE, PA, 19073, US

(21) Appl. No.: 12/460,227

(22) Filed: Jul. 15, 2009

(51) Int. Cl. B05D 7/22; C23C 14/34; C25D 5/54

(52) U.S. Cl. 427/237; 427/230; 427/239; 204/192.15; 205/85

(57) ABSTRACT

A method for passivating at least part of the feed conducting conduit of a pyrolysis furnace to reduce the deposition of coke in that conduit, the passivation being accomplished by employing at least one phosphorous containing compound.

### BACKGROUND OF THE INVENTION

1. Field of the Invention

This invention relates to the thermal cracking of hydrocarbonaceous feeds in a pyrolysis furnace. More particularly, this invention relates to the reduction of coke deposition in the feed conducting conduits (tubes) of a pyrolysis furnace.

2. Description of the Prior Art

Thermal cracking (pyrolysis) of hydrocarbons is a petrochemical process that is widely used to produce olefins such as ethylene, propylene, butenes, butadiene, and aromatics such as benzene, toluene, and xylenes.

Basically, a hydrocarbon containing feedstock is mixed with steam which serves as a diluent to keep the hydrocarbon molecules separated. The steam/hydrocarbon mixture is preheated in the convection zone of the furnace to from about 900 to about 1,000 degrees Fahrenheit (F.), and then enters the reaction (radiant) zone where it is very quickly heated to a severe hydrocarbon thermal cracking temperature in the range of from about 1,400 to about 1,550 F. Thermal cracking is accomplished without the aid of any catalyst.

This process is carried out in a pyrolysis furnace (steam cracker) at pressures in the reaction zone ranging from about 10 to about 30 psig. Pyrolysis furnaces carry internally thereof a convection section (zone) and a separate radiant section (zone). Preheating functions are primarily accomplished in the convection section, while thermal cracking occurs primarily in the radiant section.

After thermal cracking, depending on the nature of the primary feed to the pyrolysis furnace, the effluent from that furnace can contain gaseous hydrocarbons of great variety, e.g., from one to thirty-five carbon atoms per molecule. These gaseous hydrocarbons can be saturated, monounsaturated, and polyunsaturated, and can be aliphatic, alicyclics, and/or aromatic. The cracked gas can also contain significant amounts of molecular hydrogen.

The cracked product is then further processed in the olefin production plant to produce, as products of the plant, various separate individual streams of high purity such as hydrogen, ethylene, propylene, mixed hydrocarbons having four carbon atoms per molecule, fuel oil, and pyrolysis gasoline. Each separate individual stream aforesaid is a valuable commercial product in its own right. Thus, an olefin production plant currently takes a part (fraction) of a whole crude oil (crude oil) and/or condensate stream, and generates therefrom a plurality of separate, valuable products.

Thermal cracking came into use in 1913 and was first applied to gaseous ethane as the primary feed to the cracking furnace for the purpose of making ethylene. Since that time the industry has evolved to using heavier and more complex hydrocarbonaceous gaseous and/or liquid feeds as the primary feed for the cracking furnace. Such feeds now employ one or more fractions of crude oil and/or condensate which fractions are essentially totally vaporized while thermally cracking same.

Natural gas and crude oil were formed naturally in a number of subterranean geologic formations of widely varying porosities, and capped by impervious layers of rock. Natural gas and crude oil also accumulated in various stratigraphic traps below the earth's surface. Vast amounts of both natural gas and/or crude oil were thus collected to form hydrocarbon bearing formations at varying depths below the earth's surface. Much of this natural gas was in close physical contact with crude oil, and, therefore, absorbed a number of lighter molecules from the crude oil.

The terms “crude oil,” and “whole crude oil,” as used herein means liquid (at normally prevailing conditions of temperature and pressure at the earth's surface) crude oil as it issues from a wellhead separate from any natural gas that may be present, and excepting any treatment such crude oil may receive to render it acceptable for transport to a crude oil refinery and/or conventional distillation in such a refinery. Thus, it is crude oil that is suitable for distillation or other fractionation in a refinery, but which has not undergone any such distillation or fractionation. It could include, but does not necessarily always include, non-boiling entities such as asphaltenes or tar. Accordingly, crude oil could be one or more crudes straight from an oil field pipeline and/or conventional crude oil storage facility, as availability dictates, without any prior fractionation thereof.

The terms “hydrocarbon,” “hydrocarbons,” and “hydrocarbonaceous,” as used herein, do not mean materials strictly or only containing hydrogen atoms and carbon atoms. Such terms include materials that are hydrocarbonaceous in nature in that they primarily or essentially are composed of hydrogen and carbon atoms, but can contain other elements such as oxygen, sulfur, nitrogen, metals, inorganic salts, and the like, even in significant amounts.

Natural gas, like crude oil, can vary widely in its composition as produced to the earth's surface, but generally contains a significant amount, most often a major amount, i.e., greater than about 50 weight percent (wt. %), methane. Natural gas often also carries minor amounts (less than about 50 wt. %), of one or more of ethane, propane, butane, nitrogen, carbon dioxide, hydrogen sulfide, and the like. Many, but not all, natural gas streams as produced from the earth can contain minor amounts of hydrocarbons having from 5 to 12, inclusive, carbon atoms per molecule (C5 to C12) that are not normally gaseous at generally prevailing ambient atmospheric conditions of temperature and pressure at the earth's surface, and that can condense out of the natural gas once it is produced to the earth's surface. All wt. % are based on the total weight of the natural gas stream in question.

When various natural gas streams are produced to the earth's surface, a hydrocarbon composition often naturally condenses out of the thus produced natural gas stream under the then prevailing conditions of temperature and pressure at the earth's surface where that stream is collected. There is thus produced at the earth's surface a normally liquid hydrocarbonaceous condensate separate from the normally gaseous natural gas. The normally gaseous natural gas can contain methane, ethane, propane, and butane. The normally liquid hydrocarbon fraction that condenses from the produced natural gas stream is generally referred to as “condensate,” and generally contains molecules heavier than butane (C5 to about C20 or slightly higher). After separation from the produced natural gas, this liquid condensate fraction is processed separately from the remaining gaseous fraction that is normally referred to as natural gas.

Thus, condensate recovered from a natural gas stream as first produced to the earth's surface is not the exact same material, composition wise, as natural gas (primarily methane). Neither is it the same material, composition wise, as crude oil. Condensate occupies a niche between normally gaseous natural gas and normally liquid whole crude oil. Condensate contains hydrocarbons heavier than normally gaseous natural gas, and a range of hydrocarbons that are at the lightest end of whole crude oil.

Condensate, unlike crude oil, can be characterized by way of its boiling point range. Condensates normally boil in the range of from about 100 to about 650 F. With this boiling range, condensates contain a wide variety of hydrocarbonaceous materials. These materials can include compounds that make up fractions that are commonly referred to as naphtha, kerosene, diesel fuel(s), and gas oil (fuel oil, furnace oil, heating oil, and the like).

The olefin production industry is now progressing beyond the use of fractions of crude oil or condensate as the primary feed for a cracking furnace to the use of whole crude oil and/or whole condensate itself.

Heretofore, when employing less complex feeds, little or no coke was found in the convection sections of cracking furnaces, and it was common thought in the industry that coke protection in the convection section of furnaces was not necessary. However, it has been found that as the industry has progressed to the cracking of heavier feeds, the tendency to form coke in the convection section of a furnace has substantially increased. Because the primary function of the convection zone was preheating and not cracking, this tendency to form substantial amounts of coke in the convection section of the furnace was unexpected. Further, this coke formation tendency can be expected to increase even more as the industry moves toward using whole crude oil and/or condensate as a primary furnace feed.

Coke, as used herein, means a high molecular weight carbonaceous solid, and includes compounds formed from the condensation of polynuclear aromatics. Coke has heretofore been found to be formed essentially only in the radiant section of furnaces where the primary cracking of the furnace feed occurs.

Pursuant to this invention, it has been found that the coke deposition tendency of feeds described above can at least be reduced by passivation of the conduit, convection and/or radiant, that transports the feed to be cracked through the furnace.

### SUMMARY OF THE INVENTION

It has been found that by applying a coating of at least one phosphorous containing compound to the internal surface of at least part of the conduit that conducts the feed to be cracked through the furnace, the deposition of coke on the thus coated internal surface is substantially reduced.

### DESCRIPTION OF THE DRAWING

FIG. 1 shows a simplified flow sheet for the thermal cracking process described hereinabove.

FIG. 2 shows a section of a typical sinusoidal convection conduit as normally used in a cracking furnace that has been coated with a phosphorous oxide layer pursuant to this invention.

### DETAILED DESCRIPTION OF THE INVENTION

An olefin producing plant useful with this invention would include a pyrolysis furnace for initially receiving, heating, and thermally cracking a hydrocarbonaceous feed. Pyrolysis furnaces for steam cracking of hydrocarbons heat by means of convection and radiation, and comprise a series of preheating, circulation, and cracking tubes (conduits or coils), usually bundles of such tubes, for preheating, transporting, and cracking the hydrocarbon feed. The cracking heat is supplied by burners disposed in the radiant (radiation) section of the furnace. The flue gas from these burners is circulated through the convection section of the furnace to provide the heat necessary for preheating the incoming hydrocarbon feed in the convection zone. The convection and radiant sections of the furnace are joined at a “crossover” which carries the hydrocarbon feed from the interior of the convection section to the interior of the radiant section.

In a typical furnace, the convection section can contain multiple sub-zones. For example, the feed can initially be preheated in a first upper sub-zone, boiler feed water heated in a second sub-zone, mixed feed and steam heated in a third sub-zone, steam superheated in a fourth sub-zone, and the final feed/steam mixture split into multiple sub-streams and preheated in a lower (bottom) or fifth sub-zone. The number of sub-zones and their functions can vary considerably. Each sub-zone can carry a plurality of conduits carrying furnace feed there through, many of which are sinusoidal in configuration. This convection section, operating at much less severe operating conditions than the radiant section, has heretofore not been a problem in respect of coke formation and deposition therein.

Cracking furnaces are designed for rapid heating in the radiant section starting at the radiant tube (coil) inlet where reaction velocity constants are low because of low temperature. Most of the heat transferred simply raises the hydrocarbons from the inlet temperature to near the reaction temperature. In the middle of the radiant coil, the rate of temperature rise is lower but the cracking rates are appreciable. At the outlet end of this coil, the rate of temperature rise increases somewhat but not as rapidly as at the inlet. The rate of disappearance of the reactant is the product of its reaction velocity constant times its localized concentration. At the outlet of the coil, reactant concentration is low and additional cracking can be obtained, if desired, by increasing the process gas temperature.

Steam dilution of the feed hydrocarbon lowers the hydrocarbon partial pressure, enhances olefin formation, and helps reduce any tendency toward coke formation in the radiant tubes.

Cracking furnace radiant zones typically have rectangular fireboxes with upright tubes centrally located between radiant refractory walls. The tubes are supported from their top.

Firing of the radiant section is accomplished with wall or floor mounted burners or a combination of both using gaseous or combined gaseous/liquid fuels. Fireboxes are typically under slight negative pressure, most often with upward flow of flue gas. Flue gas flow into the convection section is established by at least one of natural draft or induced draft fans.

Radiant coils are usually hung in a single plane down the center of the fire box. They can be nested in a single plane or placed parallel in a staggered, double-row tube arrangement. Heat transfer from the burners to the radiant tubes occurs largely by radiation, hence the term “radiant section,” where the hydrocarbons are heated to from about 1,400 F to about 1,550 F and thereby subjected to cracking with consequent coke formation.

The initially empty radiant coil is, therefore, a fired tubular chemical reactor. Hydrocarbon feed to the furnace is preheated to from about 900 F to about 1,000 F in the convection section by convectional heating from the flue gas from the radiant section, steam dilution of the feed in the convection section, and the like. After preheating the feed is ready for entry into the radiant section.

The cracked gaseous hydrocarbons leaving the radiant section are rapidly reduced in temperature to prevent destruction of the cracking pattern. Cooling of the cracked gases before further processing of same downstream in the olefin production plant recovers a large amount of energy as high pressure steam for re-use in the furnace and/or olefin plant. This is often accomplished with the use of a transfer-line exchanger or TLE.

Processing of furnace product downstream of the TLE, although it can vary from plant to plant, typically employs an oil quench of the cooler, but still hot, cracked furnace effluent. Thereafter, the cracked hydrocarbon stream typically is subjected to primary fractionation to remove heavy liquids, followed by compression of uncondensed hydrocarbons, and acid gas and water removal therefrom. Various desired products are then individually separated, e.g., ethylene, propylene, a mixture of hydrocarbons having four carbon atoms per molecule, fuel oil, pyrolysis gasoline, and a high purity hydrogen stream.

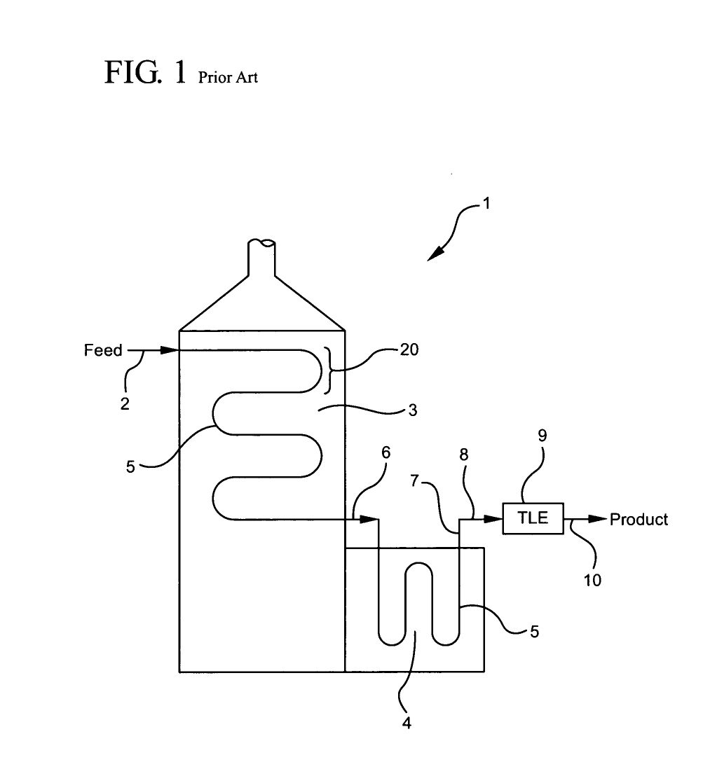

FIG. 1 is very diagrammatic for sake of clarity, and shows a typical pyrolysis furnace 1 receiving a hydrocarbon feed 2 for thermal cracking in furnace 1.

Furnace 1 has a convection heating zone 3 and a radiant heating zone 4 in fluid communication with one another by way of crossover section 6. A sinusoidal conduit 5 (essentially horizontally disposed in zone 3 and essentially vertically disposed in zone 4) conducts feed 2 through convection zone 3 for pre-heating purposes, through crossover zone 6, and then into radiant zone 4 for cracking purposes. Thus, conduit 5 is made up of a single conduit that receives feed 2 at its inlet end 2, and transports that feed through zones 3, 6, and 4 to the cracked product output end, line 7.

Feed 2 can enter furnace 1 at a temperature of from about ambient up to about 300 F at a pressure from slightly above atmospheric up to about 100 psig.

The cracked product 7 from furnace 1 is passed by way of line 8 to TLE 9 at which point the multi-step temperature quenching (cooling) process of that product begins. The cracked product leaves TLE 9 by way of line 10 for further processing in the remainder of the olefin plant downstream of furnace 1 as described hereinabove.

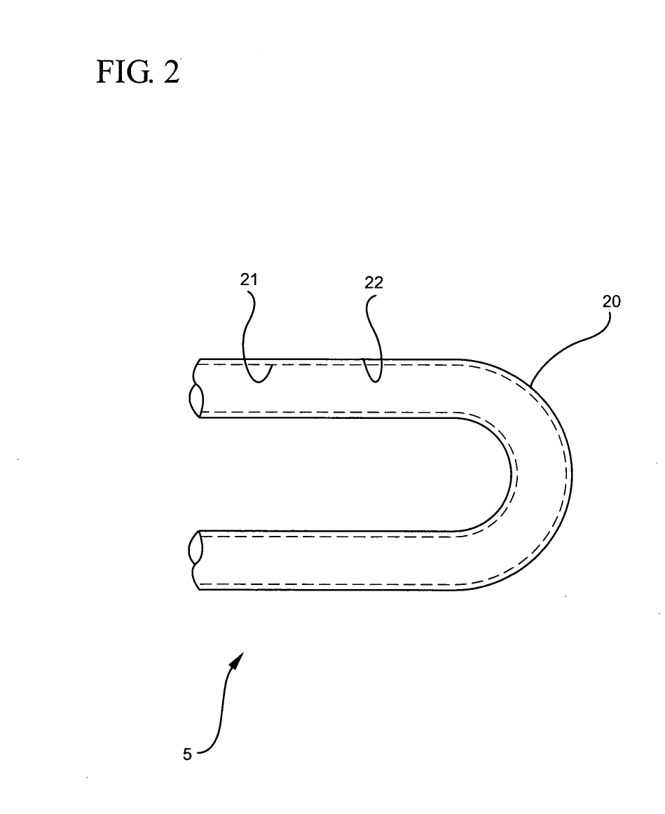

FIG. 2 shows an exemplary horizontally disposed portion 20 of conduit 5 that is designated in the upper portion of convection zone 3 of FIG. 1.

Conduit 5 is typically formed from carbon steel, but it can be formed at least in part from other steels such as stainless steel, or even other metals. However, conduit 5 is conventionally metallic. Thus, conduit 5 has its metallic internal surface 22 exposed to feed 2 at an elevated temperature which promotes the deposition of an undesired coating of coke (not shown) on internal surface 22.

Pursuant to this invention, Section 20 has been treated with at least one phosphorous oxide containing compound to form at least one layer 21 that is imposed upon and bound by chemical reaction to the internal surface 22 of conduit 5.

It has been found that by the employment of layer 21 over a substantial part, if not all, of the internal surface 22 of conduit 5 in either or all of the sections 3, 4, and/or 6, the tendency of a coke forming feed 2 to lay down coke on internal surface 22 is at least reduced, if, depending on the chemical make-up of feed 2, not essentially eliminated.

Accordingly, all or any desired portion or portions of any or all of zones 3, 4, and 6 can be coated pursuant to the process of this invention.

Layer 21 can be composed of at least one phosphorous oxide containing compound and/or at least one phosphorous sulfide containing compound. Suitable such compounds include phosphoric acid, orthophosphate, orthophosphite, phosphorous sulfides, thio phosphorous esters, and the like.

Layer 21 can be of any thickness that is effective to reduce the deposition of coke in conduit 5. Such a thickness can, therefore, vary with the nature of feed 2 passing through conduit 5. However, the thickness will generally be at least about one micron, preferably from about 1 to about 50 microns or more.

Coating 21 can be applied to internal surface area 22 in any way that is convenient for the particular furnace being treated. For example, the phosphorous containing compound(s) can be applied by painting techniques (brushing, spraying, pipeline pigging, and the like) using as many paint coats as necessary to effect the desired reduction in coke lay down. The painting technique can include a carrier fluid for suspending or dissolving the phosphorous oxide containing compound(s) until deposited onto surface 22. The carrier fluid can be gaseous or liquid that vaporizes after lay down. Such carrier liquids include water, methanol, ethanol, toluene, and mineral oil, e.g., white oil. The carrier fluid, after it evaporates, leaves the phosphorous oxide containing compound(s) in place on internal surface 22. Other application techniques can be employed, if feasible with the materials employed, such as plating, vapor deposition, sputtering, and the like. Such applications are known in the art and do not require further detail to inform the art.

Coating 21, when initially applied to all or part of internal surface area 22 in zones 3 and 4 and crossover 6 can be left to chemically react with the internal metal surface in conduit 5 to form a chemical bond between coating 21 and that internal surface 22. This can be accomplished in many cases by allowing coating 21 to remain undisturbed in physical contact with internal surface 22 under ambient conditions of temperature, pressure, and atmosphere for a time sufficient to allow the desired chemical reaction between coating 21 and conduit 5. However, in certain situations it may be desirable to facilitate such a reaction by heating the coated conduit to a temperature of at least about 450 F under ambient conditions of pressure and atmosphere for a time sufficient to effect the desired reaction and bonding.

Conduit 5, being metallic and often formed from steel, e.g., carbon steel, stainless steel, high alloy steel and the like and combinations thereof, can have spaced apart or semi-continuous oxidized portions, or even continuous oxidized portions, over all or substantially all of internal surface area 22. A particular advantage of this invention is that coating 21 is effective in reacting with and bonding to metal oxide areas on internal surface 22 as well as un-oxidized bare metal from which conduit 5 originally was formed. Thus, unsatisfactory coating and/or bonding between layer 21 and internal surface 22 due to oxidation of surface 22 is not a risk with this invention.

### EXAMPLE

A high nickel content alloy steel tubing (600HT) is treated on its surface by contact until liquid wet with a solution of orthophosphate in mineral oil containing about 5 wt. % orthophosphate based on the total weight of the solution.

The solution is allowed to react with the tubing for about 16 hours at about 194 F under atmospheric pressure and ambient air. Excess solution is drained from the tube and the tube is further heat treated for about 16 hours at about 482 F under atmospheric pressure and ambient air.

The convection zone of a pyrolysis furnace is simulated by heating the orthophosphate coated tubing at about 1,000 F under ambient conditions of pressure and atmosphere.

A feedstock composed of about 99 wt. % Bejaia condensate and about 1 wt. % Sahara Blend crude oil, all wt % based on the total weight of the feed, is passed over tubing that has not been treated with orthophosphate and tubing that has been treated in the manner aforesaid.

Feedstock is passed over both treated and untreated tubing for about 6 hours under ambient pressure and atmosphere.

Coke fouling on the treated tubing is at least about 25 percent less than on the untreated tubing.

We claim:

1. In a hydrocarbon thermal cracking furnace having a convection heating zone, a crossover zone, and a radiant heating zone, said zones carrying at least one metal conduit that transports hydrocarbon feed through said zones, said conduit having an open interior and a metallic internal surface area exposed to both said open interior and said hydrocarbon feed passing thereby, a method for reducing the deposition of coke on at least part of said internal surface area of said conduit comprising providing at least one phosphorous containing compound, and coating at least a portion of said internal surface area of at least one of said zones of said conduit with said at least one phosphorous containing compound in a thickness effective to reduce the deposition of coke on said coated internal surface area portion.

2. The method of claim 1 wherein said at least one phosphorous containing compound is selected from the group consisting of phosphorous oxide containing compounds and phosphorous sulfide containing compounds.

3. The method of claim 1 wherein said at least one phosphorous containing compound contains an effective coating amount of at least one compound selected from the group consisting of phosphoric acid, orthophosphate, orthophosphite, phosphorous sulfides, and thio phosphorous esters.

4. The method of claim 1 wherein said at least one phosphorous containing compound is applied to said internal surface under conditions that cause said phosphorous oxide containing compound to chemically react and bond with said internal surface of said conduit.

5. The method of claim 1 wherein said metallic internal surface of said conduit is at least in part oxidized and said at least one phosphorous containing compound chemically reacts and bonds with the oxidized areas of said internal surface of said conduit.

6. The method of claim 1 wherein said conduit is formed from steel.

7. The method of claim 1 wherein said coating has a thickness of at least about one micron.

8. The method of claim 1 wherein said coating is applied by at least one of painting, plating, vapor deposition, and sputtering.

9. The method of claim 1 wherein said coating after application to said internal surface is maintained at a temperature of at least about 450 F under ambient conditions of pressure and atmosphere for a time sufficient to cause chemical reaction between said internal surface and said at least one phosphorous containing compound, including any oxidized portions of said internal surface.

10. The method of claim 1 wherein at least a preponderance of said internal surface area of at least one of said zones of said conduit is coated with said at least one phosphorous containing compound.
